(19) United States
(12) Patent Application Publication
(10) Pub. No.: US 2025/0202437 A1
(43) Pub. Date: Jun. 19, 2025

(54) NOVEL DIFFERENTIAL AMPLIFIER WITH FEEDFORWARD BIAS CORRECTION CIRCUIT, AND DEVICE

(71) Applicant: SHANGHAI WEIZIMEI ELECTRONIC TECHNOLOGY CO., LTD, Shanghai (CN)

(72) Inventor: Alejandro VERA, Shanghai (CN)

(73) Assignee: SHANGHAI WEIZIMEI ELECTRONIC TECHNOLOGY CO., LTD, Shanghai (CN)

(21) Appl. No.: 18/840,580

(22) PCT Filed: Aug. 24, 2022
(86) PCT No.: PCT/CN2022/114638

§ 371 Date: Aug. 22, 2024

(30) Foreign Application Priority Data
Jul. 29, 2022 (CN) 202210903044.X

(51) Int. Cl. H03F 1/32; H03F 3/45

(52) U.S. Cl. CPC H03F 1/3211; H03F 3/45475

(57) ABSTRACT

A novel differential amplifier with a feedforward bias correction circuit, and a device. Common-mode voltage output of a differential amplifier is dynamically adjusted based on an input voltage by using a bias correction circuit. This can greatly reduce an input voltage error of the differential amplifier caused by an offset of the common-mode voltage output, so that a quite small input signal can be detected at high precision, assisting a common-mode regulation channel in tracking the common-mode voltage output, thereby reducing the offset of the common-mode voltage output and improving accuracy of the differential amplifier.

### TECHNICAL FIELD

Embodiments of this application relate to the field of differential amplifier technologies, and in particular, to a novel differential amplifier with a feedforward bias correction circuit, and a device.

### BACKGROUND

A differential amplifier, as a circuit capable of amplifying a difference between two input voltages, is a directly coupled amplifier with a quite small zero drift and is usually used for direct-current amplification. The differential amplifier may provide balanced (the term “balanced” means differential) input and output, or may provide single-terminal (unbalanced) input and output. In addition, the differential amplifier is usually configured to implement mutual conversion between a balanced circuit and an unbalanced circuit and serves as a basic unit of various integrated circuits.

During design of a fully differential amplifier, it is found that an effective bias voltage for the amplifier is related to common-mode voltage output. For a quite small input signal, the common-mode voltage output produces an unacceptably large offset, leading to low accuracy of the differential amplifier.

### SUMMARY

In view of this, embodiments of this application provide a novel differential amplifier with a feedforward bias correction circuit, and a device, so as to resolve the prior-art technical problem that common-mode voltage output produces an unacceptably large offset due to a quite small input signal, leading to low accuracy of a differential amplifier.

To achieve the foregoing objective, the following technical solutions are provided in the embodiments of this application.

According to a first aspect of the embodiments of this application, an embodiment of this application provides a differential amplifier with a feedforward bias correction circuit. The differential amplifier includes a differential amplifier and a bias correction circuit, where
the differential amplifier includes an operational amplifier, an input terminal of the bias correction circuit is connected to a high-level input terminal and a low-level input terminal of the differential amplifier, an output terminal of the bias correction circuit is connected to the operational amplifier, and the bias correction circuit dynamically adjusts common-mode voltage output of the differential amplifier based on a voltage at an input terminal of the differential amplifier.

In a preferred embodiment of this application, the differential amplifier further includes a first resistor, a second resistor, a first feedback circuit, and a second feedback circuit, where
a first terminal of the first resistor is connected to the high-level input terminal of the differential amplifier, a second terminal of the first resistor is connected to a first input terminal of the operational amplifier, a first terminal of the second resistor is connected to the low-level input terminal of the differential amplifier, a second terminal of the second resistor is connected to a second input terminal of the operational amplifier, a first terminal of the first feedback circuit is connected to the first input terminal of the operational amplifier, a first terminal of the second feedback circuit is connected to the second input terminal of the operational amplifier, a second terminal of the first feedback circuit and a second terminal of the second feedback circuit are separately connected to an output terminal of the operational amplifier.

In a preferred embodiment of this application, the bias correction circuit includes a clamping voltage setting circuit and a common-mode voltage regulation circuit, where
a first terminal of the clamping voltage setting circuit is connected to a reference voltage setting circuit, a second terminal of the clamping voltage setting circuit is connected to a first input terminal of the common-mode voltage regulation circuit, the first input terminal of the common-mode voltage regulation circuit is connected to the high-level input terminal of the differential amplifier, a second input terminal of the common-mode voltage regulation circuit is connected to the low-level input terminal of the differential amplifier, an output terminal of the common-mode voltage regulation circuit is connected to the operational amplifier, and the clamping voltage setting circuit is configured to set a clamping voltage of the common-mode voltage regulation circuit.

In a preferred embodiment of this application, the clamping voltage setting circuit includes a buffer amplifier and a third resistor, where a first input terminal of the buffer amplifier is connected to the reference voltage setting circuit, a second input terminal of the buffer amplifier is connected to a common terminal between an output terminal of the buffer amplifier and a first terminal of the third resistor, and a second terminal of the third resistor is connected to a high-level input terminal of the common-mode voltage regulation circuit.

In a preferred embodiment of this application, the common-mode voltage regulation circuit includes a fourth resistor, a fifth resistor, and a differential amplifier, where
a first terminal of the fourth resistor is connected to the high-level input terminal of the differential amplifier, a second terminal of the fourth resistor is connected to a first input terminal of the differential amplifier, a first terminal of the fifth resistor is connected to the low-level input terminal of the differential amplifier, a second terminal of the fifth resistor is connected to a second input terminal of the differential amplifier, and an output terminal of the differential amplifier is connected to the operational amplifier so as to input a reference common-mode voltage set by the differential amplifier to the operational amplifier.

In a preferred embodiment of this application, the differential amplifier is an instrumentation amplifier.

In a preferred embodiment of this application, the common-mode voltage regulation circuit further includes a second feedback circuit, where a first terminal of the second feedback circuit is connected to a common terminal between the second terminal of the fifth resistor and the second input terminal of the differential amplifier.

Compared with the prior art, the embodiments of this application provide a novel differential amplifier with a feedforward bias correction circuit, and a device. Common-mode voltage output of a differential amplifier is dynamically adjusted based on an input voltage by using a bias correction circuit. This can greatly reduce an input voltage error of the differential amplifier caused by an offset of the common-mode voltage output, so that a quite small input signal can be detected at high precision, assisting a common-mode regulation channel in tracking the common-mode voltage output, thereby reducing the offset of the common-mode voltage output and improving accuracy of the differential amplifier.

According to a second aspect, an embodiment of this application further provides a device including the differential amplifier according to the first aspect.

Compared with the prior art, the beneficial effects of the device provided in this embodiment of this application are the same as that of the differential amplifier provided in the first aspect. Details are not described herein again.

### BRIEF DESCRIPTION OF DRAWINGS

To describe the technical solutions of the embodiments of this application or in the prior art more clearly, the following briefly describes the accompanying drawings required for describing the embodiments or the prior art. Apparently, the accompanying drawings in the following descriptions are merely examples, and persons of ordinary skill may still derive other implementation drawings from the provided accompanying drawings without creative efforts.

A structure, a proportion, a size, and the like shown in this specification are merely intended to match content disclosed in this specification to facilitate understanding and reading by persons skilled in the art, but not intended to limit a limiting condition under which this application can be implemented, and therefore have no technical significance. Any structural modification, proportional relationship change, or size adjustment shall still fall within the scope covered by technical content disclosed in this application without affecting effect that can be produced by this application or objectives that can be achieved by this application.

FIG. 1 is a schematic structural diagram of a differential amplifier provided in the prior art;

FIG. 2 is a schematic structural diagram of a differential amplifier with a feedforward bias correction circuit according to an embodiment of this application;

FIG. 3 is a schematic structural diagram of a differential amplifier used in a battery charger according to an embodiment of this application; and

FIG. 4 is a schematic structural diagram of a differential amplifier used in a battery charger according to an embodiment of this application.

### DETAILED DESCRIPTION OF EMBODIMENTS

Embodiments of this application are described below by using specific embodiments. Persons skilled in the art can easily understand other advantages and effects of this application from content disclosed in this specification. Apparently, the described embodiments are some but not all of the embodiments of this application. All other embodiments obtained by persons of ordinary skill in the art based on the embodiments of this application without creative efforts shall fall within the protection scope of this application.

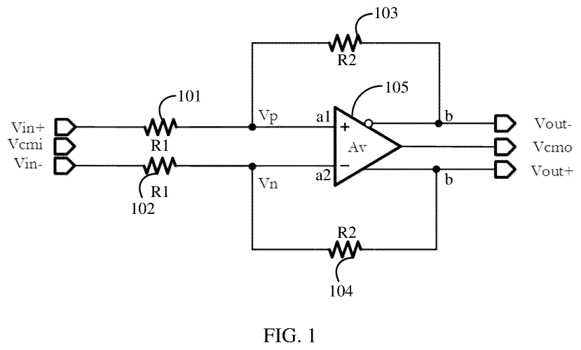

FIG. 1 is a circuit diagram of a differential amplifier provided in the prior art. The differential amplifier in the prior art includes an operational amplifier 105, a first resistor (R1) 101, a second resistor (R1) 102, a first feedback circuit (R2) 103, and a second feedback circuit (R2) 104.

A first terminal of the first resistor 101 is connected to a high-level input terminal Vᵢₙ₊ of the differential amplifier. A second terminal of the first resistor 101 is connected to a first input terminal a1 of the operational amplifier 105. A first terminal of the second resistor 102 is connected to a low-level input terminal Vᵢₙ₋ of the differential amplifier. A second terminal of the second resistor 102 is connected to a second input terminal a2 of the operational amplifier 105. A first terminal of the first feedback circuit 103 is connected to the first input terminal a1 of the operational amplifier 105. A first terminal of the second feedback circuit 104 is connected to the second input terminal a2 of the operational amplifier 105. A second terminal of the first feedback circuit 103 and a second terminal of the second feedback circuit 104 are separately connected to an output terminal b of the operational amplifier 105.

The existing differential amplifier has common-mode voltage input V_{cmi}, common-mode voltage output V_{cmo}, the high-level input terminal Vᵢₙ₊, the low-level input terminal Vᵢₙ₋, a high-level output terminal Vₒᵤₜ₊, and a low-level output terminal Vₒᵤₜ₋. If an open-loop gain of the differential amplifier tends to be infinite, an output voltage of the differential amplifier (Vₒᵤₜ₊−Vₒᵤₜ₋) is calculated according to the following formula:

$${V}_{out +} - {V}_{out -} = ( {V}_{in +} - {V}_{in -} ) \frac{R 2}{R 1} \qquad ( I )$$

R1 indicates resistances of the first resistor 101 and the second resistor 102, and the resistances of the first resistor 101 and the second resistor 102 are the same. R2 indicates resistances of the first feedback circuit 103 and the second feedback circuit 104, and the resistances of the first feedback circuit 103 and the second feedback circuit 104 are the same. In a circuit of the differential amplifier, the first resistor (R1) 101, the second resistor (R1) 102, the first feedback circuit (R2) 103, and the second feedback circuit (R2) 104 are configured to set a gain of the differential amplifier. A value of R2/R1 is used to set a closed-loop gain ratio of the differential amplifier. The gain ratio may range from 20 times to 100 times, and the gain may alternatively be larger. This is not limited in this embodiment of this application.

It is assumed that an open-loop gain of the differential amplifier tends to be infinite and an offset of common-mode voltage output may be ignored. An output error V_{out,ε,cm} of the differential amplifier caused by a mismatch between independent resistors R2 is calculated according to the following formula:

$${V}_{out , ε , c m} = {V}_{cmo} ( ( \frac{R 1 + R 2}{R 1 + R 2 ( 1 + σ )} ) - 1 ) \qquad ( II )$$

V_{cmo} is the common-mode voltage output. R1 indicates resistances of the first resistor 101 and the second resistor 102, and the resistances of the first resistor 101 and the second resistor 102 are the same. R2 indicates resistances of the first feedback circuit 103 and the second feedback circuit 104, and the resistances of the first feedback circuit 103 and the second feedback circuit 104 are the same. In practical application of an integrated circuit, two devices are not exactly the same due to a subtle change during manufacturing. Therefore, two resistors R2 are represented by a value of R2 and a value of (1+σ)×R2, where σ is an error change between two R2. Similar analysis may also be performed for R1, but results are quite similar. The output error V_{out,ε,cm} of the differential amplifier is obtained by multiplying the common-mode voltage output V_{cmo} by the gain of the differential amplifier.

It can be learned from the formula (II) that the output error V_{out,ε,cm} of the differential amplifier is mainly determined by the first resistor (R1) 101, the second resistor (R1) 102, the first feedback circuit (R2) 103, the second feedback circuit (R2) 104, and the common-mode voltage output V_{cmo}.

It can be learned from the prior art that, to reduce the output error V_{out,ε,cm} of the differential amplifier so as to improve accuracy of the differential amplifier, the common-mode voltage output V_{cmo} needs to be reduced. The embodiments of this application provide the following technical solutions.

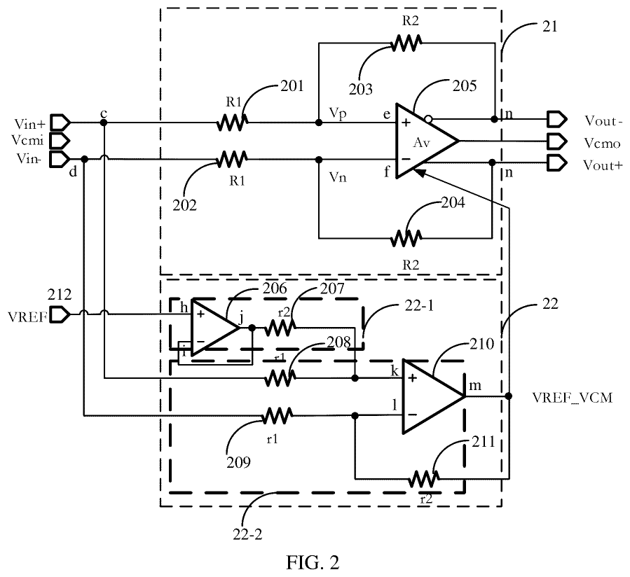

As shown in FIG. 2, an embodiment of this application provides a novel differential amplifier with a feedforward bias correction circuit. The novel differential amplifier includes a differential amplifier 21 and a bias correction circuit 22.

The differential amplifier 21 includes an operational amplifier 205.

An input terminal c and an input terminal d of the bias correction circuit 22 are connected to a high-level input terminal Vᵢₙ₊ and a low-level input terminal Vᵢₙ₋ of the differential amplifier respectively. An output terminal m of the bias correction circuit 22 is connected to the operational amplifier 205. The bias correction circuit 22 dynamically adjusts common-mode voltage output of the differential amplifier based on an input voltage of the differential amplifier 21.

The differential amplifier 21 further includes a first resistor (R1) 201, a second resistor (R1) 202, a first feedback circuit (R2) 203, and a second feedback circuit (R2) 204.

A first terminal of the first resistor (R1) 201 is connected to the high-level input terminal Vᵢₙ₊ of the differential amplifier. A second terminal of the first resistor (R1) 201 is connected to a first input terminal e of the operational amplifier 205. A first terminal of the second resistor (R1) 202 is connected to the low-level input terminal Vᵢₙ₋ of the differential amplifier. A second terminal of the second resistor (R1) 202 is connected to a second input terminal f of the operational amplifier 205. A first terminal of the first feedback circuit (R2) 203 is connected to the first input terminal e of the operational amplifier 205. A first terminal of the second feedback circuit (R2) 204 is connected to the second input terminal f of the operational amplifier 205. A second terminal of the first feedback circuit (R2) 203 and a second terminal of the second feedback circuit (R2) 204 are separately connected to an output terminal n of the operational amplifier 205.

The bias correction circuit 22 includes a clamping voltage setting circuit 22-1 and a common-mode voltage regulation circuit 22-2. A first terminal of the clamping voltage setting circuit 22-1 is connected to a reference voltage setting circuit 212. A second terminal of the clamping voltage setting circuit 22-1 is connected to a first input terminal k of the common-mode voltage regulation circuit 22-2. The first input terminal k of the common-mode voltage regulation circuit 22-2 is connected to the high-level input terminal Vᵢₙ₊ of the differential amplifier. A second input terminal 1 of the common-mode voltage regulation circuit 22-2 is connected to the low-level input terminal Vᵢₙ₋ of the differential amplifier. An output terminal m of the common-mode voltage regulation circuit 22-2 is connected to the operational amplifier 205. The clamping voltage setting circuit 22-1 is configured to set a clamping voltage of the common-mode voltage regulation circuit 22-2.

The clamping voltage setting circuit 22-1 includes a buffer amplifier 206 and a third resistor (r2) 207. A first input terminal h of the buffer amplifier 206 is connected to the reference voltage setting circuit 212. A second input terminal i of the buffer amplifier 206 is connected to a common terminal between an output terminal j of the buffer amplifier 206 and a first terminal of the third resistor (r2) 207. A second terminal of the third resistor (r2) 207 is connected to a common terminal between a second terminal of a fourth resistor (r1) 208 and a first input terminal k of a differential amplifier 210.

The buffer amplifier 206 is configured to prevent overloading of the reference voltage setting circuit 212. The reference voltage setting circuit 212 is usually overloaded in a band gap circuit. The reference voltage setting circuit 212 also has quite high impedance in the case of overloading. Any overloading affects a reference voltage (VREF) of the reference voltage setting circuit 212. The buffer amplifier 206 can retain accuracy of the reference voltage (VREF) of the reference voltage setting circuit 212. The third resistor (r2) 207 can reduce a clamping voltage of the bias correction circuit 22.

The common-mode voltage regulation circuit 22-2 includes the fourth resistor (r1) 208, a fifth resistor (r1) 209, and the differential amplifier 210. A first terminal of the fourth resistor (r1) 208 is connected to the high-level input terminal Vᵢₙ₊ of the differential amplifier, and a second terminal of the fourth resistor (r1) 208 is connected to the first input terminal k of the differential amplifier 210. A first terminal of the fifth resistor (r1) 209 is connected to the low-level input terminal Vᵢₙ₋ of the differential amplifier, and a second terminal of the fifth resistor (r1) 209 is connected to a second input terminal i of the differential amplifier 210. An output terminal m of the differential amplifier 210 is connected to the operational amplifier 205. The differential amplifier 210 is an instrumentation amplifier. The differential amplifier 210 calculates a difference between the high-level input terminal Vᵢₙ₊ and the low-level input terminal Vᵢₙ₋ of the differential amplifier, and then calculates a sum of the difference and the reference voltage (VREF) of the reference voltage setting circuit 212. A reference common-mode voltage VREF_VCM output by the differential amplifier 210 is calculated according to the following formula (III):

$$VREF\_VCM = ( 1 + \frac{{r}_{1}}{{r}_{2}} ) \times ( \frac{V REF ( r 1 ) + {V}_{in +} ( r 2 )}{{r}_{2} + {r}_{2}} ) \qquad ( III )$$

The reference common-mode voltage VREF_VCM is set by using the instrumentation amplifier 210. The reference common-mode voltage VREF_VCM set by the common-mode voltage setting circuit is used to adjust common-mode voltage output of the differential amplifier. The reference common-mode voltage VREF_VCM is also another input terminal of the differential amplifier, to facilitate adjustment of the common-mode voltage output of the differential amplifier. To reduce the influence of the common-mode voltage output on the differential amplifier, the reference common-mode voltage VREF_VCM is set based on an input voltage Vᵢₙ(Vᵢₙ₊−Vᵢₙ₋) by using the instrumentation amplifier 210.

The common-mode voltage regulation circuit 22-2 further includes a second feedback circuit (r2) 211, where a first terminal of the second feedback circuit (r2) 211 is connected to a common terminal between the second terminal of the fifth resistor (r1) 209 and the second input terminal i of the differential amplifier 210.

Each differential amplifier has common-mode voltage input and output. When a mismatch occurs between the first feedback circuit (R2) 203 and the second feedback circuit (R2) 204, the common-mode voltage output causes degradation of accuracy of the differential amplifier. In this embodiment of this application, the bias correction circuit 22 in the differential amplifier adjusts the common-mode voltage output based on an input voltage to reduce a common-mode error.

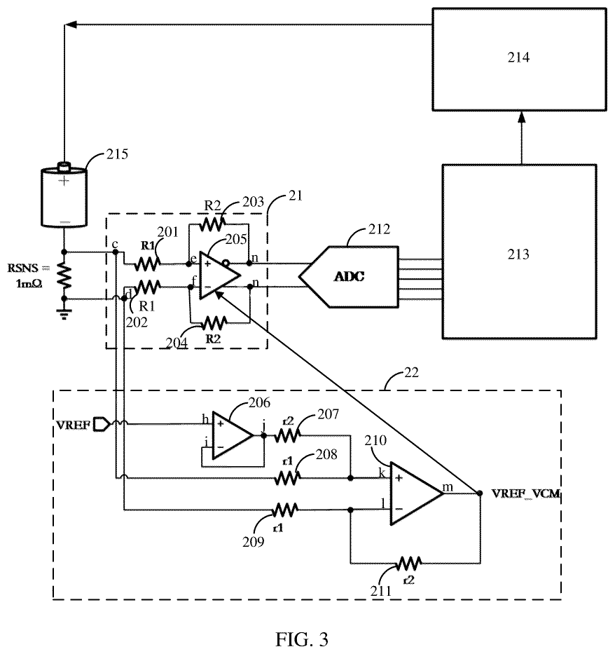

As shown in FIG. 3, the differential amplifier provided in this embodiment of this application is used in a battery charger with a quite low inductive resistance. In this embodiment of this application, a current may be detected at quite high precision and adjusted, allowing for extended battery life, thereby implementing charging at higher precision, preventing damage to the battery, and reducing a risk of a fire.

In a specific battery charger, a negative electrode of a battery 215 is connected to a fixed voltage node through an inductive resistor RSNS, so that a battery current can be measured more accurately. An output terminal n of an operational amplifier 205 is connected to an analog-to-digital converter ADC 212. The analog-to-digital converter ADC 212 is a type of device for converting a continuous analog signal into a discrete digital signal. The analog-to-digital converter ADC 212 is connected to a digital controller 213. The digital controller 213 usually has a program for converting an input signal into an output signal. The digital controller 213 completes a specific control algorithm through programming by using computer software. The digital controller 213 is connected to a positive electrode of the battery 215 through a DC/DC converter 214. The DC/DC converter 214 is configured to convert an input voltage into a fixed effective output voltage. The battery charger adjusts a current of the battery by using the differential amplifier provided in this embodiment of this application, preventing damage to the battery.

In battery charging application, because the inductive resistor RSNS is directly connected in a current path, the inductive resistor RSNS is configured to produce a voltage drop for retaining low impedance and reducing power loss. Therefore, a high-fidelity amplifier needs to be used to detect a low voltage that passes through the inductive resistor RSNS, and amplify the voltage to enable the analog-to-digital converter ADC 212 to correctly perform reading. A gain of the differential amplifier 21 may range from 20 times to 100 times. A specific gain multiple depends on a current requirement of the battery, an input requirement of the analog-to-digital converter ADC 212, and selection of the inductive resistor RSNS. The instrumentation amplifier 210 is configured to sample an input voltage and adjust the common-mode voltage output of the differential amplifier 21 to improve accuracy of the differential amplifier.

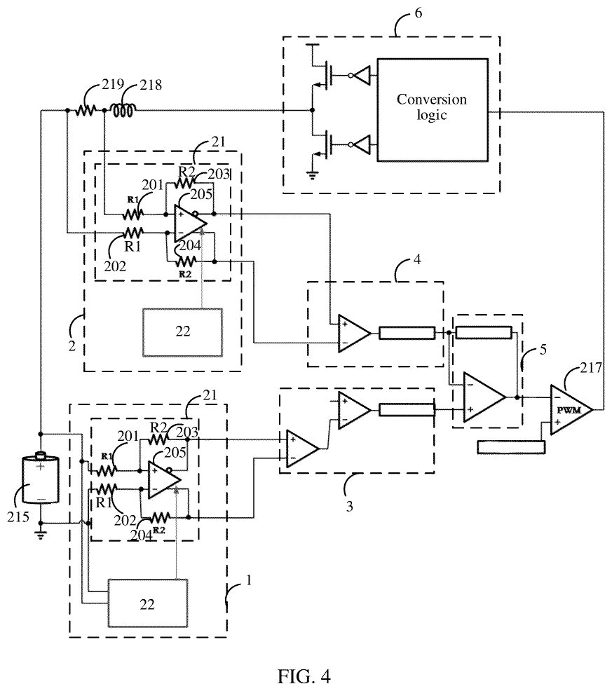

As shown in FIG. 4, the differential amplifier provided in this embodiment of this application is used in a battery charger. An average current mode battery charger may have a plurality of high-accuracy differential amplifiers, and each differential amplifier has its own bias correction circuit. In this embodiment of FIG. 3, at a position at which a current is accurately measured, a same structure may be used to accurately measure a battery voltage. In FIG. 4, a novel differential amplifier 2 is used to detect a battery current, and another novel differential amplifier 1 is used to detect an inductor current. A negative electrode of a battery 215 is connected to a fixed voltage node, and a positive electrode is connected to the novel differential amplifier 1 of this application. The differential amplifier 1 includes a differential amplifier 21 and a bias correction circuit 22. The novel differential amplifier 1 and a periodic current detection module 3 detect a battery current. An output terminal of the periodic current detection module 3 is connected to a current error amplifier 5. An output terminal of the current error amplifier 5 is connected to an input terminal of a pulse width modulator 217 to modulate a pulse width. An output terminal of the pulse width modulator 217 is connected to a buck conversion logic module 6. The buck conversion logic module 6 is sequentially connected to an inductor 218 and a resistor 219. The novel differential amplifier 1 is connected to two terminals of the resistor 219 so as to detect currents at the two terminals of the resistor 219.

In this embodiment of this application, the differential amplifier 1 and the differential amplifier 2 each have a bias correction circuit 22 to enhance regulation control of a direct current/direct current converter loop. Regulation accuracy of an average current mode loop can be improved through more accurate detection of an inductor current. In this embodiment of this application, a current may be detected at quite high precision and adjusted, allowing for extended battery life, thereby implementing charging at higher precision, preventing damage to the battery, and reducing a risk of a fire.

According to a second aspect, an embodiment of this application further provides a device including the differential amplifier according to the first aspect.

Compared with the prior art, the beneficial effects of the device provided in this embodiment of this application are the same as that of the differential amplifier provided in the first aspect. Details are not described herein again.

Although this application is described above in detail by using general descriptions and specific embodiments, it is apparent to persons skilled in the art that some modifications or improvements may be made based on this application. Therefore, these modifications or improvements made without departing from the spirit of this application fall within the protection scope of this application.

1-8. (canceled)

9. A differential amplifier with a feedforward bias correction circuit comprising a differential amplifier and a bias correction circuit,
the differential amplifier comprising: an operational amplifier, an input terminal of the bias correction circuit is connected to a high-level input terminal and a low-level input terminal of the differential amplifier, an output terminal of the bias correction circuit is connected to the operational amplifier, and the bias correction circuit dynamically adjusts common-mode voltage output of the differential amplifier based on a voltage at an input terminal of the differential amplifier.

10. The novel differential amplifier with a feedforward bias correction circuit according to claim 9, further comprising a first resistor, a second resistor, a first feedback circuit, and a second feedback circuit, wherein
a first terminal of the first resistor is connected to the high-level input terminal of the differential amplifier, a second terminal of the first resistor is connected to a first input terminal of the operational amplifier, a first terminal of the second resistor is connected to the low-level input terminal of the differential amplifier, a second terminal of the second resistor is connected to a second input terminal of the operational amplifier, a first terminal of the first feedback circuit is connected to the first input terminal of the operational amplifier, a first terminal of the second feedback circuit is connected to the second input terminal of the operational amplifier, a second terminal of the first feedback circuit and a second terminal of the second feedback circuit are separately connected to an output terminal of the operational amplifier.

11. The novel differential amplifier with a feedforward bias correction circuit according to claim 10, wherein the bias correction circuit comprises a clamping voltage setting circuit and a common-mode voltage regulation circuit, wherein
a first terminal of the clamping voltage setting circuit is connected to a reference voltage setting circuit, a second terminal of the clamping voltage setting circuit is connected to a first input terminal of the common-mode voltage regulation circuit, the first input terminal of the common-mode voltage regulation circuit is further connected to the high-level input terminal of the differential amplifier, a second input terminal of the common-mode voltage regulation circuit is connected to the low-level input terminal of the differential amplifier, an output terminal of the common-mode voltage regulation circuit is connected to the operational amplifier, and the clamping voltage setting circuit is configured to set a clamping voltage of the common-mode voltage regulation circuit.

12. The novel differential amplifier with a feedforward bias correction circuit according to claim 11, wherein the clamping voltage setting circuit comprises a buffer amplifier and a third resistor, wherein a first input terminal of the buffer amplifier is connected to the reference voltage setting circuit, a second input terminal of the buffer amplifier is connected to a common terminal between an output terminal of the buffer amplifier and a first terminal of the third resistor, and a second terminal of the third resistor is connected to a high-level input terminal of the common-mode voltage regulation circuit.

13. The novel differential amplifier with a feedforward bias correction circuit according to claim 11, wherein the common-mode voltage regulation circuit comprises a fourth resistor, a fifth resistor, and a differential amplifier, wherein
a first terminal of the fourth resistor is connected to the high-level input terminal of the differential amplifier, a second terminal of the fourth resistor is connected to a first input terminal of the differential amplifier, a first terminal of the fifth resistor is connected to the low-level input terminal of the differential amplifier, a second terminal of the fifth resistor is connected to a second input terminal of the differential amplifier, and an output terminal of the differential amplifier is connected to the operational amplifier so as to input a reference common-mode voltage set by the differential amplifier to the operational amplifier.

14. The novel differential amplifier with a feedforward bias correction circuit according to claim 13, wherein the differential amplifier is an instrumentation amplifier.

15. The differential amplifier with a feedforward bias correction circuit according to claim 12, wherein the common-mode voltage regulation circuit further comprises a second feedback circuit, wherein a first terminal of the second feedback circuit is connected to a common terminal between a second terminal of a fifth resistor and a second input terminal of the differential amplifier.

16. A device, comprising the differential amplifier according to claim 9.
